(19) United States
(12) Patent Application Publication
(10) Pub. No.: US 2024/0113171 A1
(43) Pub. Date: Apr. 4, 2024

(54) SEMICONDUCTOR DEVICE AND METHOD OF MANUFACTURING THE SAME

(71) Applicant: RENESAS ELECTRONICS CORPORATION, Tokyo (JP)

(72) Inventor: Yanzhe WANG, Tokyo (JP)

(21) Appl. No.: 18/365,447

(22) Filed: Aug. 4, 2023

(30) Foreign Application Priority Data
Oct. 4, 2022 (JP) 2022-160610

(51) Int. Cl. H01L 29/06; H01L 21/66; H01L 23/00

(52) U.S. Cl. CPC H01L 29/0696; H01L 22/32; H01L 24/05; H01L 2224/05553; H01L 2924/12036

(57) ABSTRACT

The present disclosure relates technique capable of electrically monitoring a recess amount of a semiconductor substrate. That is, a semiconductor device includes the semiconductor substrate of a first conductivity type having a first main surface and a second main surface, a first area provided on the first main surface, and a second region provided on the first main surface between the first areas. The second area includes an evaluation element. The evaluation element includes: a first semiconductor region of a second conductivity type provided in the first main surface side; a second semiconductor region of the first conductivity type provided on the first main surface side of the first semiconductor region; a first electrode pad in contact with the first semiconductor region; and a second electrode pad in contact with the second semiconductor region.

### CROSS-REFERENCE TO RELATED APPLICATIONS

The disclosure of Japanese Patent Application No. 2022-160610 filed on Oct. 4, 2022, including the specification, drawings and abstract is incorporated herein by reference in its entirety.

### BACKGROUND

The present disclosure relates to a semiconductor device, and is applicable to, for example, the semiconductor device that monitors a recess quantity of a semiconductor substrate.

In Japanese Unexamined Patent Application Publication No. 2012-238745 (Patent Document 1) discloses as followings. In the manufacturing process of the semiconductor device, at least one monitor element (monitor pattern) for evaluating electrical characteristics of semiconductor chips, and a monitor element electrode pad electrically connected to the monitor element for conducting an operation test of the monitor element are formed on the semiconductor substrate. And the electrical characteristics of the semiconductor chip are inspected by bringing the probe into contact with the monitor element electrode pads. It is due to monitor the electrical characteristics of semiconductor chips and quickly detect defects.

### SUMMARY

In a contact process for connecting a Si or other semiconductor substrate to a metal wiring, a wet etch may be performed to reduce damage to the semiconductor substrate due to dry etching. However, the etching rate of wet etching of the semiconductor substrate 1s unstable. If it is excessively etched, a recess may be formed in the semiconductor substrate.

Other objects and novel features will become apparent from the description of this specification and the accompanying drawings.

An outline of a typical one of the present disclosure will be briefly described as follows. That is, a semiconductor device includes a semiconductor substrate of a first conductivity type having a main surface, a first area provided on the main surface, and a second area provided on the main surface. The second area includes an evaluation element. The evaluation element includes: a first semiconductor region of a second conductivity type provided in the main surface; a second semiconductor region of the first conductivity type provided in the main surface of the first semiconductor region; a first electrode pad in contact with the first semiconductor region; and a second electrode pad in contact with the second semiconductor region. The second semiconductor region has a minimum depth portion of the second semiconductor region in a cross-sectional view.

According to the semiconductor device describe the above, the recess amount of the semiconductor substrate can be electrically monitored.

### BRIEF DESCRIPTION OF THE DRAWINGS

FIG. 1 is an overall plan view of a semiconductor device according to an embodiment.

FIG. 2 is an enlarged plan view of a semiconductor region shown in FIG. 1.

FIG. 3 is an enlarged plan view of a broken line portion shown in FIG. 1.

FIG. 4 is a main portion cross-sectional view along A-A′ of the semiconductor device shown in FIG. 3.

FIG. 5 is a main portion cross-sectional view along B-B′ of the semiconductor device shown in FIG. 3.

FIG. 6 is a main portion cross-sectional view along C-C′ of the semiconductor device shown in FIG. 3.

FIG. 7 is a cross-sectional view for explaining a manufacturing method of a semiconductor device shown in FIG. 1.

FIG. 8 is a cross-sectional view for explaining the manufacturing method of the semiconductor device shown in FIG. 1.

FIG. 9 is a cross-sectional view for explaining the manufacturing method of the semiconductor device shown in FIG. 1.

FIG. 10 is a cross-sectional view for explaining the manufacturing method of the semiconductor device shown in FIG. 1.

FIG. 11 is a cross-sectional view for explaining the manufacturing method of the semiconductor device shown in FIG. 1.

FIG. 12 is a layout diagram showing an ion-implantation mask pattern openings and contact opening patterns for forming the monitor element shown in FIG. 3.

FIG. 13 is a diagram showing an ion-implantation forming an N+-type semiconductor region.

FIG. 14 is a diagram showing the relationship between a width of the N+ resist and a N+ profile.

FIG. 15 is a schematic upper surface diagram of the semiconductor device in a modified example.

FIG. 16 is an enlarged plan view of the device shown in FIG. 15.

FIG. 17 is a main portion cross-sectional view along D-D′ line of the semiconductor device shown in FIG. 15.

### DETAILED DESCRIPTION

Hereinafter, an embodiment and a modified example will be described with reference to the drawings. For clarity of explanation, the following description and drawings are appropriately omitted and simplified. In addition, the same reference letter may be assigned to the same constituent elements, and repeated explanations thereof may be omitted.

A semiconductor device according to an embodiment will be described with reference to FRD (Fast Recovery Diode). FRD is used, for example, in freewheel diode connected in parallel to power device such as IGBT (Insulated Gate Bipolar Transistor).

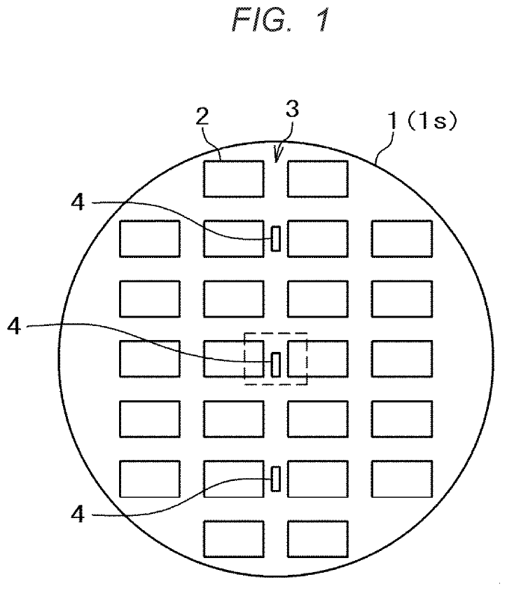

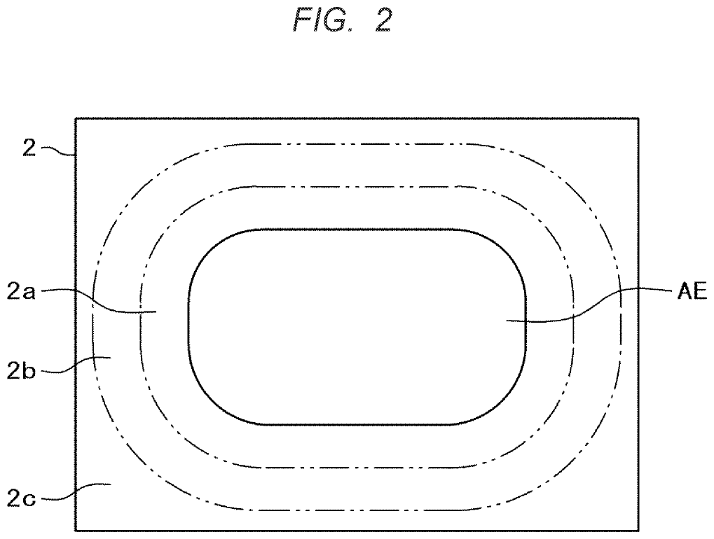

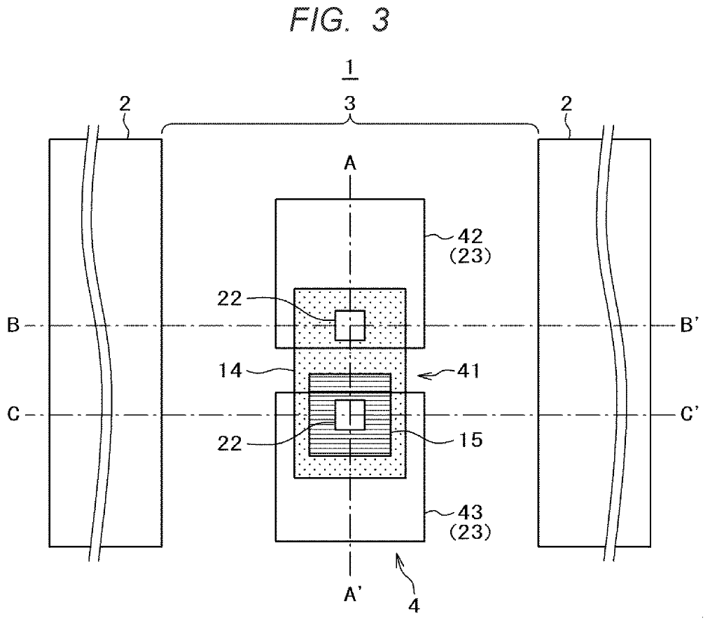

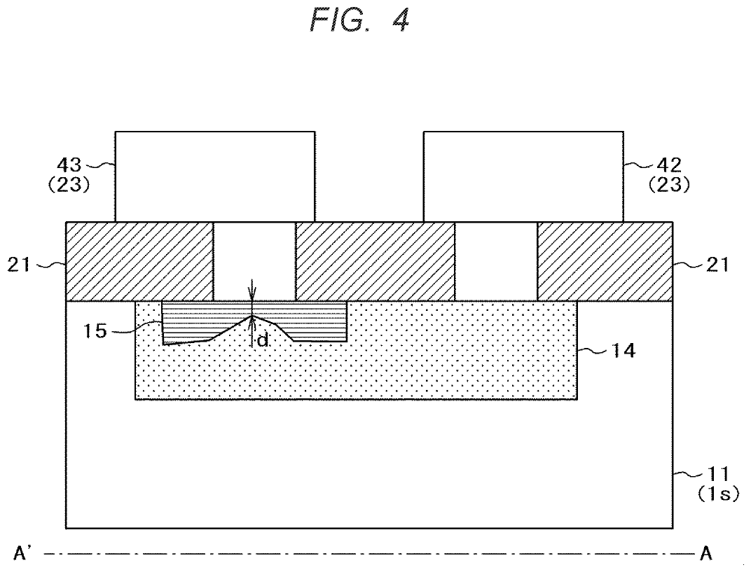

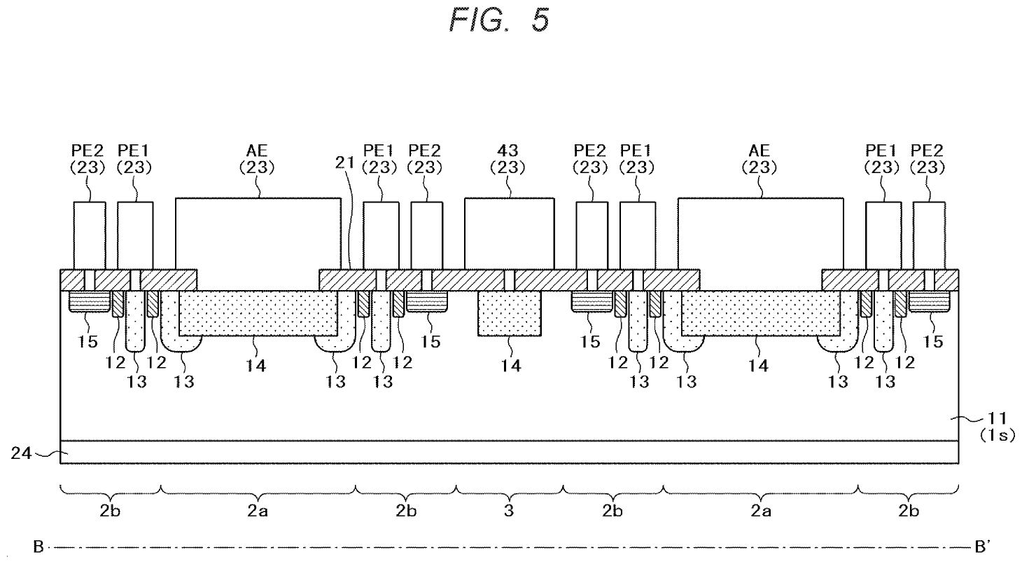

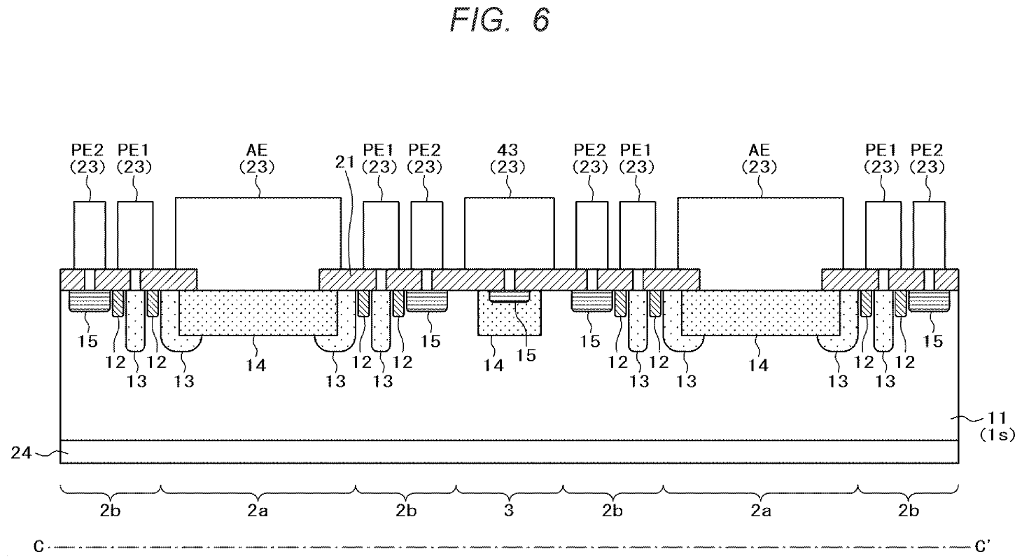

The configuration of the semiconductor device according to the embodiment will be described referring to FIG. 1 to FIG. 6. FIG. 1 is an overall plan view of the semiconductor device according to an embodiment. FIG. 2 is an enlarged plan view of a semiconductor region shown in FIG. 1. FIG. 3 is an enlarged plan view of a broken line portion shown in FIG. 1. FIG. 4 is a main portion cross-sectional view along A-A′ of the semiconductor device shown in FIG. 3. FIG. 5 is a main portion cross-sectional view along B-B′ of the semiconductor device shown in FIG. 3. FIG. 6 is a main portion cross-sectional view along C-C′ of the semiconductor device shown in FIG. 3.

The semiconductor device 1 in the embodiment has a semiconductor substrate 1s. The semiconductor substrate 1s has a surface as one main surface (first main surface) and a bottom surface as the other main surface (second main surface) opposite to the one main surface (first main surface). Note that the semiconductor device 1 may have a configuration in which conductivity types (P-type or N-type) such as the semiconductor substrate and semiconductor layer (semiconductor region) are inverted. Therefore, when the conductivity type of one of the N-type and the P-type is a first conductivity type and the other conductivity type is a second conductivity type, the first conductivity type may be the P-type and the second conductivity type may be the N-type, and conversely, the first conductivity type may be the N-type and the second conductivity type may be the P-type.

As shown in FIG. 1, the semiconductor device 1 is formed by forming a plurality of first areas that is a plurality of semiconductor chip areas 2 having a rectangular shape in plan view in a matrix shape. The region between an adjacent semiconductor chip areas 2 is second area that is a scribe area 3. The number, arrangement, and the like of the semiconductor chip areas 2 are appropriately designed. evaluation elements 4 are disposed in the scribe area 3. The evaluation elements 4 are elements for finding manufacturing problems that occur in semiconductor chips, and is called a TEG (Test Element Group). In the illustrated example, three evaluation elements 4 are arranged, but the present invention is not limited thereto, and may be two or less or four or more. In this specification, the scribe area 3 is also referred to as an evaluation element forming region. The semiconductor device 1 is divided into individual semiconductor chip in a dicing process.

As shown in FIG. 2, the semiconductor chip area 2 includes a cell region (first area) 2a, a peripheral region 2b, and an outer peripheral region (second area) 2c. The peripheral region 2b is provided on the outer peripheral side of the semiconductor chip area 2 with respect to the cell region 2a. The outer peripheral region 2c is provided on the outer peripheral side of the semiconductor chip area 2 with respect to the peripheral region 2b.

The cell region 2a is provided with an anode electrode AE. A part of the anode electrode AE serves as an electrode pad for connecting a bonding wire or the like. The anode electrode AE is covered with an insulating film (not shown) except for a portion serving as an electrode pad.

The peripheral region 2b is provided with peripheral electrodes, which will be described later. The peripheral electrodes PE1 and PE2 are provided on an outer peripheral side of the semiconductor chip area 2 with respect to the anode electrode AE.

As shown in FIG. 3, the evaluation element 4 includes a monitor element 41, a first electrode pad 42 and a second electrode pad 43. The monitor element (monitor pattern) 41 is a monitor pattern for evaluating an element characteristic or the like of the semiconductor chip area 2 in a manufacturing process of the semiconductor device 1. The electrode pads 42 and 43 are pads that are electrically connected to the monitor element 41 to perform an electric characteristic test of the monitor element 41. The electric characteristics of the monitor device is evaluated by contacting a probe with each of the electrode pads 42 and 43.

As shown in FIG. 4, the monitor element 41 is a diode for evaluating the element characteristic of a semiconductor element in the semiconductor chip area 2, and is formed on the first main surface of the semiconductor device 1. An interlayer insulating film 21 is formed so as to cover the first main surface. A metal layer 23 is formed on the interlayer insulating film 21 and a contact hole (opening) 22 formed in interlayer insulating film 21.

The monitor element 41 is provided on a N-type drift region 11 configuring a main portion of the semiconductor substrate 1s. The monitor element 41 includes a first semiconductor region (P-type body region) 14 and a second semiconductor region (N+-type semiconductor region) 15 provided on an upper surface of the P-type body region 14 on the semiconductor substrate 1s. The P-type body region 14 is a semiconductor region of a P-type conductivity type, and the N+-type semiconductor region 15 is a semiconductor region of an N-type conductivity type that opposites to the P-type conductivity type. Here, the N+-type semiconductor region 15 has a higher impurity concentration than the N-type drift region 11.

A shape of an interface between the first semiconductor region (P-type body region) 14 and the second semiconductor region (N+-type semiconductor region) 15 in a minimum depth (d) portion of the second semiconductor region (N+-type semiconductor region) 15 is a concave shape in a direction toward the first main surface.

As shown in FIG. 5, in the cell region 2a, the P-type body region 14 and a P-type third semiconductor region (P-type field region) 13 are provided on the N-type drift region 11. The P-type body region 14 is electrically connected to the anode electrode AE. The P-type field region 13 is provided deeper than the P-type body region 14. The P-type field region 13 formed in the cell region 2a is a semiconductor layer provided to widen a current path between the P-type body region 14 and the N-type drift region 11 to reduce the current density. In the peripheral region 2b, the N+-type semiconductor region 15 is provided. The N+-type semiconductor region 15 is electrically connected to the peripheral electrode PE2. And the P-type field-region 13 is provided deeper than the N+-type semiconductor region 15. The P-type field region 13 is electrically connected to the peripheral electrode PE1. The peripheral electrodes PE1 and PE2 are not electrodes for connecting the bonding wire or the like such as the anode electrode AE, and no potential is applied thereto. In FIG. 5, the peripheral electrode PE1 connected to the P-type field region 13 and the P-type field region 13 are shown one by one, but the present embodiment is not limited thereto, and two or more peripheral electrodes PE1 may be used. In addition, an isolation region 12 is provided between the P-type field region 13 and the N+-type semiconductor region 15 and between the P-type field region 13 and the P-type field region 13 of the cell region 2a. The isolation region 12 is formed of, for example, LOCOS (LOCal Oxidation of Silicon). The isolation region 12 (so-called field oxide film) and the P-type field region 13 formed in the peripheral region 2b are regions in which the electric field is relaxed by extending a depletion layer to the outer peripheral region 2c, thereby improving breakdown voltage of the diode. In addition, the N+-type semiconductor region 15 formed in the peripheral region 2b has a function of suppressing the depletion layer from reaching an end portion of the semiconductor chip constituting the individual diodes.

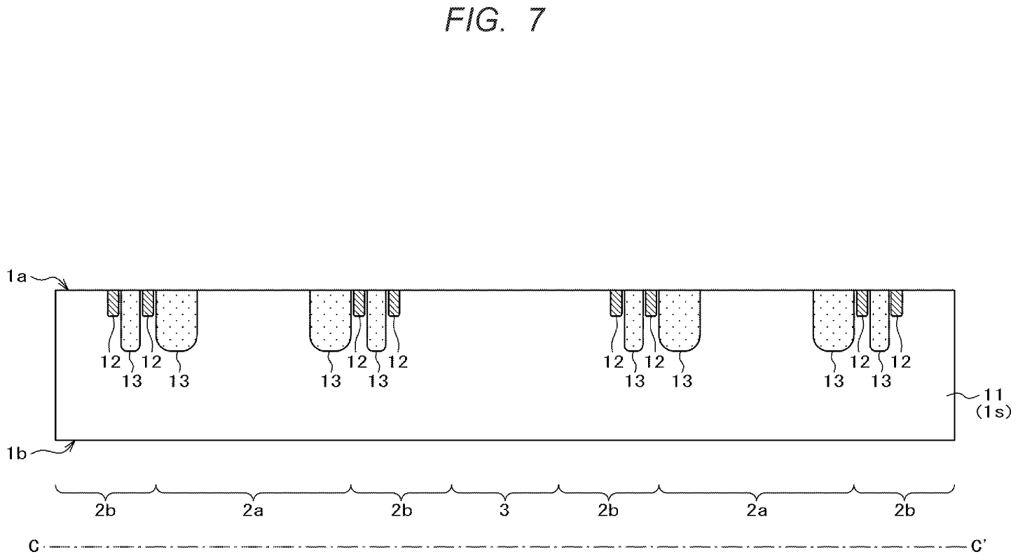

Manufacturing method of the semiconductor device 1 will be described with reference to FIGS. 7 to 11. FIGS. 7 to 11 are cross-sectional view for explaining a manufacturing method of the semiconductor device shown in FIG. 1. FIGS. 7-11 are cross-sectional view of the same cross-section as cross-sectional view of FIG. 6.

First, as shown in FIG. 7, a semiconductor wafer made of a monocrystalline silicon semiconductor substrate 1s into which an N-type impurity such as phosphorus is introduced is prepared. The semiconductor wafer has the first main surface 1a and the second main surface (bottom surface) 1b opposite to the first main surface 1a.

An impurity concentration of the N-type impurity in the semiconductor wafer can be, for example, about 2×1014 cm-3. A thickness of the semiconductor wafer may be, for example, about 450 micrometers to 1000 micrometers.

Next, a silicon nitride film (Si3N4) is formed on the first main surface of the semiconductor wafer, and the Si3N4 film is patterned to form a Si3N4 film mask. The isolation region 12 is formed by oxidizing the surface of the semiconductor wafer in a region other than Si3N4 film mask region in an oxidizing atmosphere.

Next, a P-type field region 13 is formed by introducing a P-type impurity into the semiconductor substrate 1s on the first main surface 1a of the semiconductor wafer by ion-implantation method using a resist pattern as a mask. As ion-implantation condition at this time, for example, an ionic species is boron (B) can be exemplified.

Next, after removing the resist, annealing is performed, for example, at about 1200 degree Celsius for about 30 minutes in an atmosphere of a nitrogen (N₂) gas as an inert gas, and the crystal defects are repaired and stretched and diffused in the P-type field region 13.

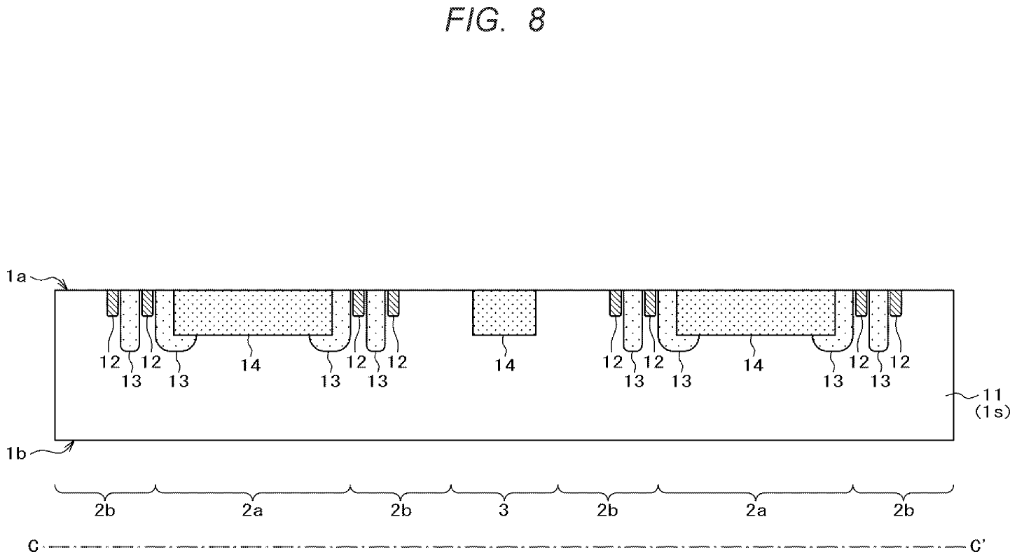

Next, as shown in FIG. 8, the P-type body region 14 is formed by introducing a P-type impurity into a required portion of the cell region 2a and the scribe area 3 by ion-implantation method using a mask as a resist pattern.

Specifically, the P-type body region 14 is formed on the P-type field region 13 and the N-type drift region 11 (1s) formed in the cell region 2a. The P-type body region 14 is formed on the N-type drift region 11 (1s) of the scribe area 3.

As ion-implantation condition at this time, for example, a ion-implantation condition in which the ionic species is boron(B), an dose amount is about 1×1013 cm-2, and the implantation energy is about 75 keV can be exemplified as a preferable condition. After removing the resist, for example, annealing at about 1000 degree Celsius. for about 100 minutes is performed in a nitrogen (N2) atmosphere.

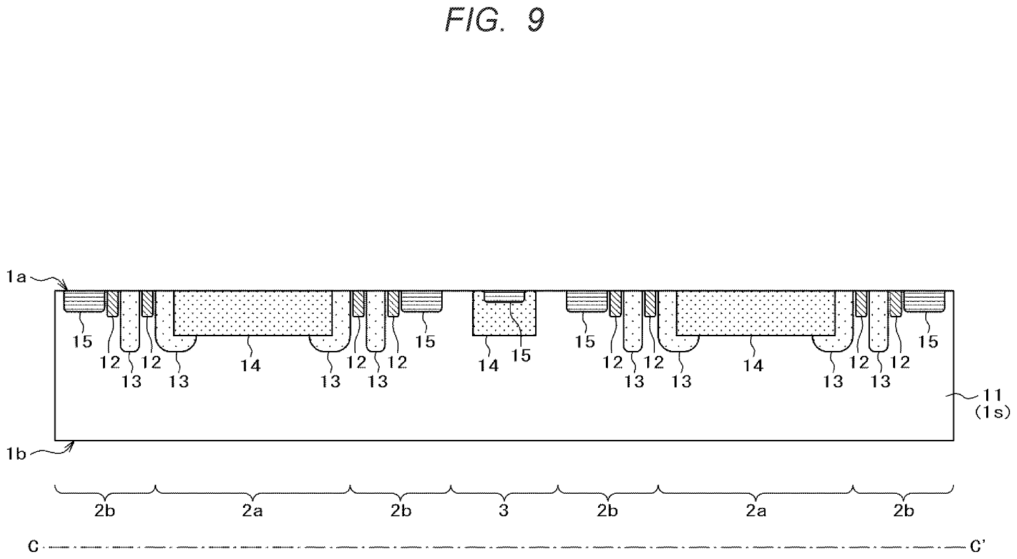

Next, as shown in FIG. 9, the N+-type semiconductor region 15 is formed by introducing an N-type impurity into the N-type drift region 11 (1s) of the peripheral region 2b and the P-type body region 14 of the scribe area 3 by ion-implantation method using the resist pattern as a mask.

As ion-implantation condition at this time, for example, a As may be used as the ionic species, an dose amount is about 5×1015 cm-2, and a 80 keV implantation energy. After removing the resist, for example, annealing at about 1000 degree Celsius. for about 100 minutes is performed in a nitrogen (N2) atmosphere.

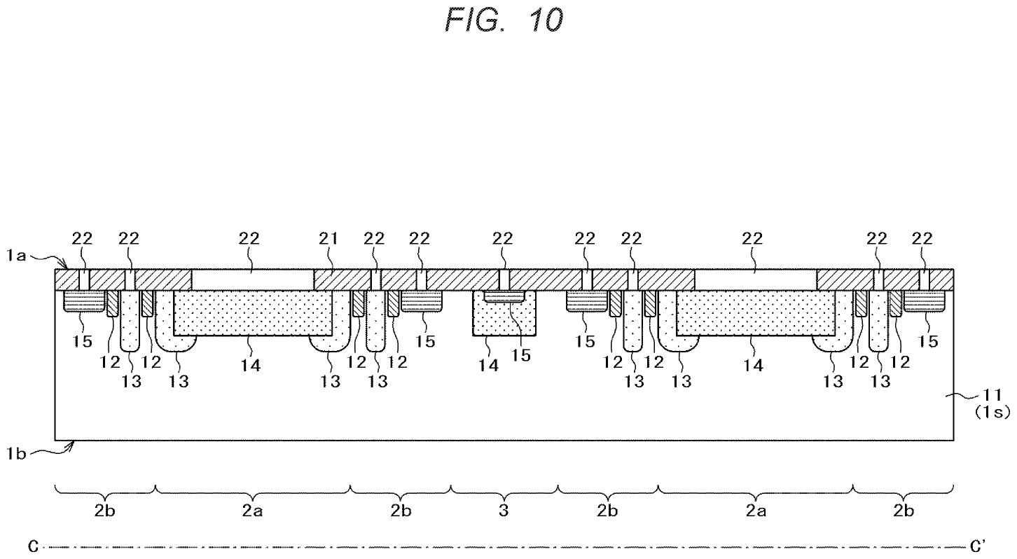

Next, as shown in FIG. 10, the interlayer insulating film 21 made of, for example, a PSG (Phospho Silicate Glass) film is formed on the first main surface 1a of the wafer by, for example, CVD method. The interlayer insulating film 21 is formed to cover, for example, the N-type drift region 11 (1s), the P-type field region 13, the P-type body region 14, and the N+-type semiconductor region 15. A thickness of the interlayer insulating film 21 is, for example, about 0.6 micrometers. As the material of the interlayer insulating film 21, in addition to the PSG film, a BPSG (Boro Phospho Silicate Glass) film, a NSG (Non-doped Silicate Glass) film, a SOG(Spin-On-Glass) film, a silicon oxide (SiO₂) film, or a composite film thereof, and the like can be exemplified as a suitable one.

Next, the contact hole (opening) 22 is formed in the interlayer insulating film 21 by anisotropic dry etching method using a mask as a resist pattern. As the anisotropic dry etching gas, for example, a mixed gas composed of argon (Ar) gas, trifluoromethane (CHF3) gas, and tetrafluoromethane (CF4) gas can be exemplified as a suitable gas.

Subsequently, in order to reduce damage to a semiconductor substrate surface caused by dry etching, the contact hole 22 and the semiconductor substrate 1s are etched by SEZ wet etching method using the interlayer insulating film 21 as a mask. As an etchant for SEZ wet etching, for example, a mixed solution of nitric acid (HNO3) and hydrofluoric acid (HF) can be exemplified as a suitable etchant.

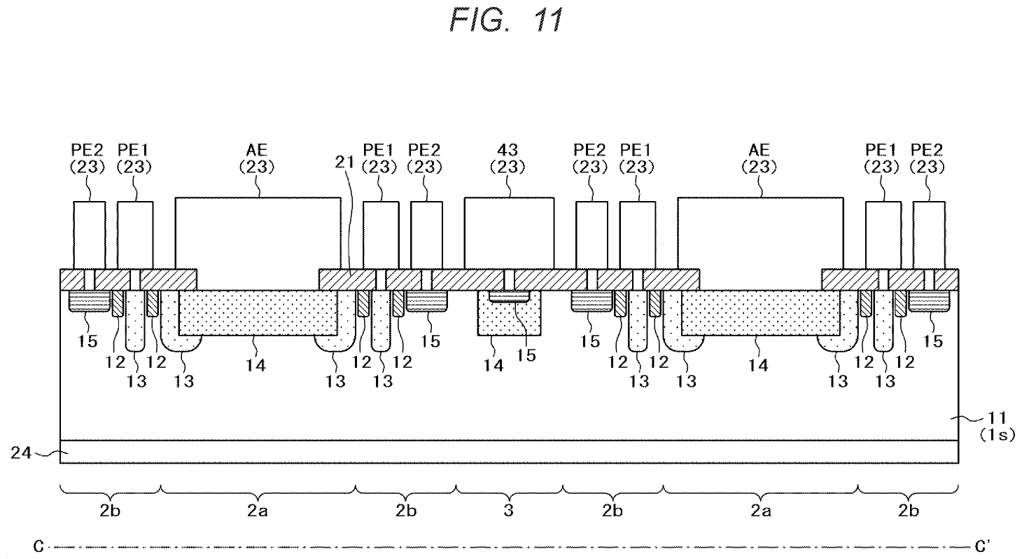

Next, as shown in FIG. 11, the metal layer 23 such as the anode electrode AE are formed. Specifically, for example, the processing is performed by the following procedure. First, an aluminum-based metal film (e.g., a few percent silicon-doped aluminum) is formed on the entire first main surface 1a of the wafer by, for example, sputtering method so as to fill in the contact hole 22. The thickness of the aluminum-based metal film is, for example, about 5 micrometers.

Next, the metal layer 23 made of the aluminum-based metal film are formed by dry etching method using a mask as a resist pattern. As the gas of dry etching, for example, chlorine (Cl2) and boron trichloride (BCl3) gas can be exemplified as a suitable gas.

As a result, in the cell region 2a, the anode electrode AE is formed inside the contact hole 22 and on the interlayer insulating film 21. In the scribe area 3, the electrode pads 42 and 43 are formed inside the contact hole 22 and on the interlayer insulating film 21. Here, the metal layer 23 in the contact hole 22 is referred to as a contact portion.

The anode electrode AE is electrically connected to the P-type body region 14 formed in the cell region 2a. The electrode pad 42 is electrically connected to the P-type body region 14 formed in the scribe area 3, and the electrode pad 43 is electrically connected to the N+-type semiconductor region 15 formed in the scribe area 3.

Next, on the anode electrode AE, an insulating film as a passivation film made of, for example, a polyimide-based organic film or the like is formed. The thickness of the insulating film is, for example, about 2.5 micrometers. Next, the insulating film is patterned by dry etching method using a mask as a resist pattern to form the contact hole (opening) 22 that penetrates the insulating film and reaches the anode electrode AE. Then, an anode pad formed of the anode electrode AE exposed in the contact hole (opening) 22 is formed.

Next, the second main surface 1b of the semiconductor wafer is subjected to a back grinding process, whereby a thickness of, for example, about 800 micrometers is thinned to, for example, about 30 micrometers to 200 micrometers as needed. If required, chemical etching or the like for removing damage to the second main surface 1b is also performed.

Next, a cathode electrode 24 electrically connected to the N-type drift region 11 (1s) is formed on the second main surface 1b of the wafer by, for example, sputtering method. Thereafter, the semiconductor substrate 1s is divided into the plurality of semiconductor chip areas 2 by dicing or the like, and sealed in a packaging as needed, thereby substantially completing semiconductor chip as the semiconductor device.

As described above, in the contact forming process of connecting the semiconductor substrate 1s in which the P-type body region is formed and the metal layer 23, wet etching is performed in order to reduce damage to the semiconductor substrate 1s due to dry etching. The etching rate of the wet etching of Si constituting the semiconductor substrate 1s is unstable. If it is excessively etched, a recess may be formed in the semiconductor substrate 1s, and a RRSOA breakdown may occur.

Therefore, in the embodiment, a Si recess amount is monitored by the evaluation element 4. Referring to FIG. 4, a method for monitoring the Si recess amount by the evaluation element 4 will be described.

A reference voltage (V1) is applied to the electrode pad 42 and a voltage (V2) is applied to the electrode pad 43 to measure a current between the electrode pads 42 and 43. Here, in case of V2>V1, a reverse-voltage is applied to a PN junction diode which is formed in the monitor element 41. If a Si recess amount exceeds the minimum depth (d) of the N+-type semiconductor region 15, the PN junction diode fail and large current flows. The amount of the Si recess amount is monitored by this method.

By forming a plurality of N+-type semiconductor region 15 having different minimum depth (d) portions and measuring the current, the monitor of the Si recess amounts can be multi-valued.

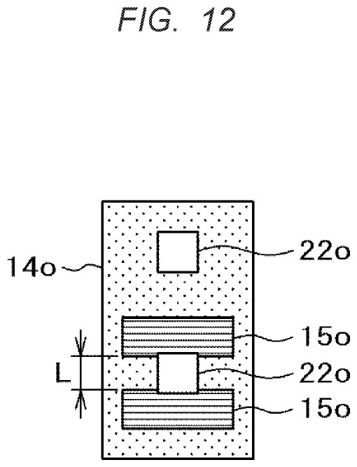

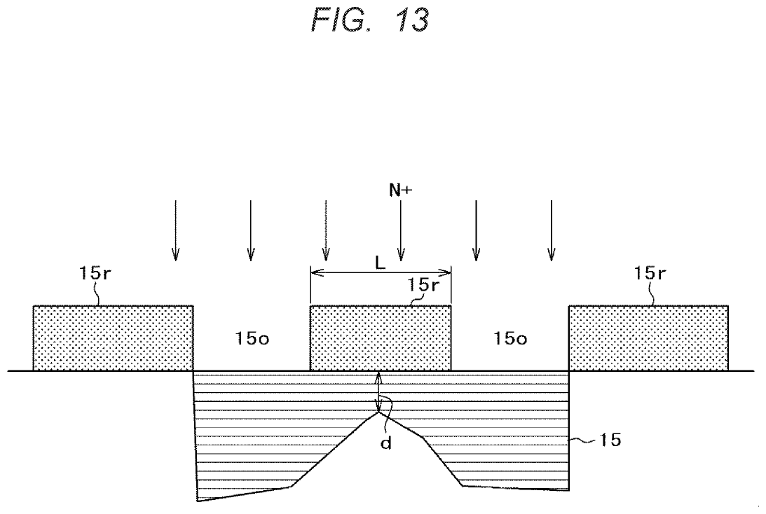

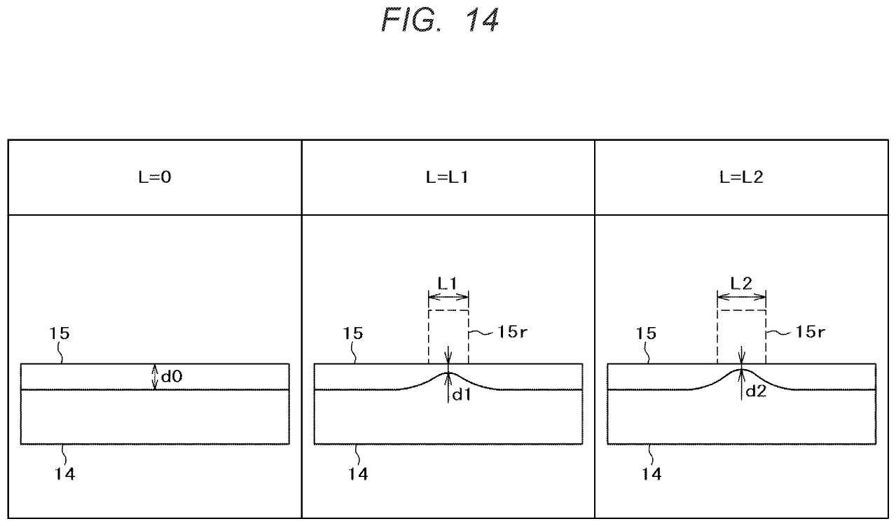

Referring to FIGS. 12 to 14, a plurality of N+-type semiconductor region 15 having the different minimum depth (d) portions will be described. FIG. 12 is a layout diagram showing ion-implantation mask pattern openings and contact opening patterns for forming the monitor element 41 shown in FIG. 3. FIG. 13 is a diagram showing an ion-implantation forming the N+-type semiconductor region 15. FIG. 14 is a diagram showing the relationship between a width of the N+ resist and a N+ profile.

As described above, the P-type body region 14 is formed by introducing a P-type impurity into a required portion of the scribe area 3 by ion-implantation method using a mask as a resist pattern. The opening region of the resist pattern used at this time is a P-type body injection opening region 14o shown in FIG. 12.

As described above, the N+-type semiconductor region 15 is formed by introducing an N-type impurity onto the P-type body region 14 of the scribe area 3 by ion-implantation method using the resist pattern as mask. This ion-implantation is called N+ implantation. The opening region of the resist pattern used at this time is the N+ implantation opening region 15o shown in FIG. 12. The resist at this time is the N+ resist 15r shown in FIG. 13.

As described above, the contact hole 22 is formed in the interlayer insulating film 21 by anisotropic dry etching method using the resist pattern as mask. The opening area of the resist pattern used at this time is the control opening area 22o shown in FIG. 12.

Even in the N+ implantation under the same condition, the minimum depth (d) portion can be modulated as shown in FIG. 14 by changing the width (L) of the middle N+ resist 15r shown in FIG. 13, and the monitor of the Si recess amount can be multi-valued.

When there is no N+ resist 15r (L=0), a depth of the impurity concentration profile (N+ profile) from the surface of the semiconductor substrate 1s of the N-type impurity in the depth direction is substantially uniform. The minimum depth at this case is defined as d0.

When the width of the N+ resist 15r is L1 (L=L1>0), a depth of the N+ profile becomes shallow. The minimum depth at this case is defined as d1, it is d1<d0.

When the width of the N+ resist 15r is L2 (L=L2>L1), the depth of the N+ profile becomes further shallower. The minimum depth at this case is defined as d2, it is d2<d1.

The minimum depth (d) is set to a plurality of values, for example, in a range of 40 nm or more and 200 nm or less.

Note that, if the desired minimum depth cannot be obtained by adjusting only the width of the N+ resist 15r, the implantation conditions and the implantation-diffusion annealing condition of the N+-type semiconductor region 15 may be adjusted.

According to the present embodiment, the Si recess amount can be monitored by electric characteristic measurement. Further, by providing the plurality of evaluation elements 4, the monitor of the Si recess amount can be multi-valued. In addition, in FRD, since there is a process of forming the P-type body region 14 of the cell region and a process of N+ implantation of the outermost periphery of the chip in the peripheral region 2b, the evaluation element can be formed without adding a process, and no additional cost is required.

Hereinafter, an exemplary modified example of the embodiment will be described. In the following explanation of modified example, it is assumed that the same reference letter as in the above-described embodiment can be used for parts having the same configuration and function as those described in the above-described embodiment. The description of the above-described embodiments can be appropriately incorporated within the scope of technical inconsistencies. In addition, some or all of the above-described embodiments and all or a part of modified example may be applied in a combined manner as appropriate within a range not technically inconsistent.

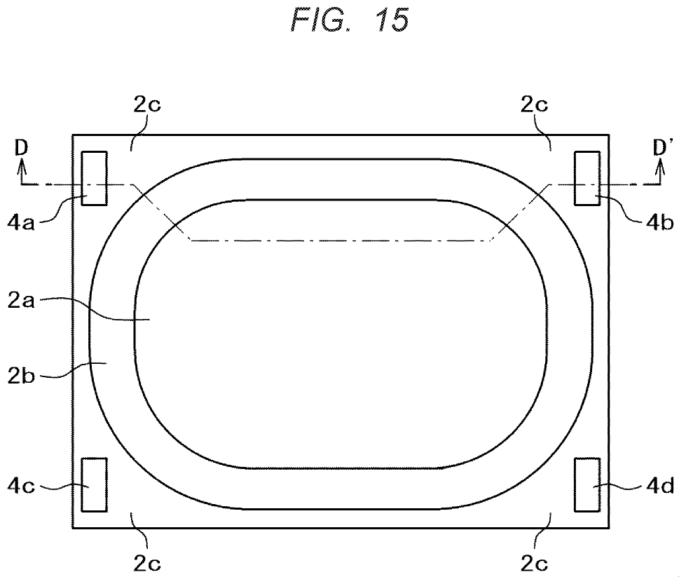

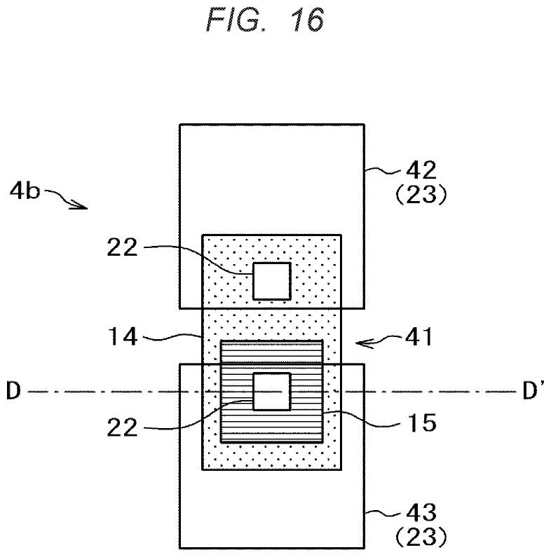

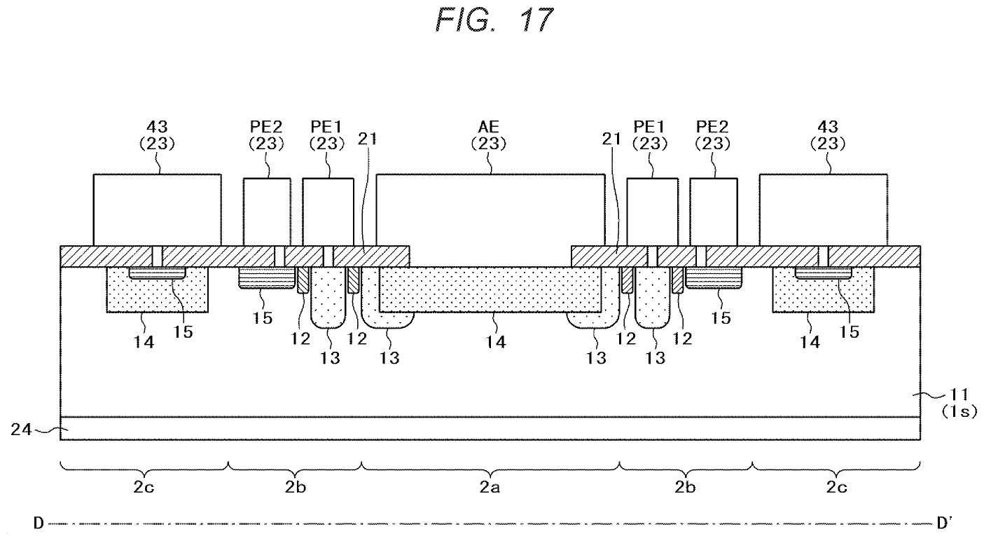

In the embodiment, the evaluation elements 4 are arranged in the scribe area 3, however it may be arranged near the corner of the peripheral region 2b of the semiconductor chip area 2. The semiconductor device in modified example will be described referring to FIG. 15. FIG. 15 is a schematic upper surface diagram of the semiconductor device in modified example. FIG. 16 is an enlarged plan view of the device shown in FIG. 15. FIG. 17 is a main portion cross-sectional view along D-D′ line of the semiconductor device shown in FIG. 15.

As shown in FIG. 15, the semiconductor chip area 2 in modified example has evaluation elements 4a,4b,4c and 4d in the outer peripheral region 2c of the semiconductor chip area 2 in the embodiment. The evaluation elements 4a,4b,4c and 4d are provided in the outer peripheral region 2c (evaluation element region). As shown in FIGS. 16 and 17, the evaluation elements 4a,4b,4c and 4d are the same structure as the evaluation element 4 in the embodiment. As described above, the semiconductor device 1 is divided into individual semiconductor chip in the dicing step. This divided semiconductor chip is also called the semiconductor device.

However, the minimum depth (d) of each N+ semiconductor region 15 of the evaluation elements 4a,4b,4c and 4d is different, and if depths are defined as d1, d2, d3 and d4, it is d1<d2<d3<d4, for example. Thus, Si recess amount can be monitored for each semiconductor chip.

Although the disclosure made by the inventor of the present disclosure has been specifically described based on the embodiments and modified example, the present disclosure is not limited to the above-described embodiments and modified example, and it is needless to say that the present disclosure can be variously modified.

What is claimed is:

1. A semiconductor device comprising:
a semiconductor substrate of a first conductivity type having a main surface;
a plurality of first areas provided on the main surface;
a second area provided on the main surface between the first areas;
an evaluation element in the second area; wherein
the evaluation element includes;
a first semiconductor region of a second conductivity type opposite to the first conductivity type formed in the second area,
a second semiconductor region of the first conductivity type formed on the first semiconductor region,
a first electrode pad electrically connected to the first semiconductor region and provided to a reference voltage to the first semiconductor region, and
a second electrode pad electrically connected to the second semiconductor region and provided to a voltage lower than the reference voltage to the second semiconductor region, wherein
the second semiconductor region has a minimum depth portion of the second semiconductor region in a cross-sectional view.

2. The semiconductor device according to claim 1, wherein
the first semiconductor region is a region introduced n-type impurities, and
the second semiconductor region is a region introduced p-type impurities opposite to the n-type impurities.

3. The semiconductor device according to claim 1, wherein
the first semiconductor region is a region introduced p-type impurities, and
the second semiconductor region is a region introduced n-type impurities opposite to the p-type impurities.

4. The semiconductor device according to claim 2, wherein
the first semiconductor region and the second semiconductor region are configured a PN-junction diode.

5. The semiconductor device according to claim 1, wherein
a shape of an interface between the first semiconductor region and the second semiconductor region in the minimum depth portion of the second semiconductor region is a concave shape in a direction toward the main surface.

6. The semiconductor device according to claim 1, wherein
a depth of the minimum depth portion of the second semiconductor region is 40 nm or more and 200 nm or less.

7. The semiconductor device according to claim 1, wherein
a plurality of evaluation elements is formed in the second area, and
depths of the minimum depth portion of a plurality of second semiconductor region in each of the plurality of evaluation elements is different each other.

8. The semiconductor device according to claim 7, wherein
the depths of the minimum depth portion of the plurality of second semiconductor region in each of the plurality of evaluation elements is 40 nm or more and 200 nm or less.

9. The semiconductor device according to claim 4, wherein
a reverse-voltage is applied to the PN-junction diode via the first electrode pad and the second electrode pad.

10. The semiconductor device according to claim 1, wherein
the plurality of first areas is a plurality of semiconductor chip areas, and
the second area is a scribe area demarcating the plurality of semiconductor chip areas.

11. The semiconductor device according to claim 1, wherein
the plurality of first areas is a plurality of cell region in a plurality of first areas, and
the second area is an outer peripheral region in the plurality of first areas.

12. A manufacturing method of a semiconductor device having an evaluation element region, comprising the steps of:
(a) forming a first semiconductor region of a p-type conductivity in the evaluation element region by introducing p-type impurities in a main surface of a semiconductor substrate of a n-type conductivity opposite to the p-type conductivity;
(b) forming resist patterns to covering areas other than the first semiconductor region and a portion in the first semiconductor region in plan view,
(c) after the step of (b), forming a second semiconductor region of the n-type conductivity by introducing n-type impurities by using the resist patterns as masks,
(d) after the step of (c), removing the resist patterns,
(e) after the step of (d), annealing the semiconductor substrate to activate the first semiconductor region and the second semiconductor region,
(f) forming an interlayer insulating film on the main surface of the semiconductor substrate,
(g) forming a first opening penetrating through the interlayer insulating film and reaching the first semiconductor region, and forming a second opening penetrating through the interlayer insulating film and reaching the second semiconductor region,
(h) forming a metal layer on the interlayer insulating film so as to fill in the first opening and the second opening, and
(i) forming a first electrode pad on the first opening and forming a second electrode pad on the second opening by patterning the metal layer, wherein
the second semiconductor region has a minimum depth portion of the second semiconductor region in a cross-sectional view.

13. The manufacturing method of the semiconductor device according to claim 12, wherein
in the step of (b), the resist pattern in the first semiconductor region has a width, and
by changing the width of the resist pattern in the first semiconductor region, the minimum depth portion of the second semiconductor region is changed.

14. The manufacturing method of the semiconductor device, according to claim 13, wherein
the depth of the minimum depth portion of the second semiconductor region is 40 nm or more and 200 nm or less.

15. The manufacturing method of the semiconductor device, according to claim 12, wherein
a plurality of evaluation element regions is formed in the semiconductor substrate,
in the step of (b), width of the resist pattern formed within the first semiconductor regions are different in the plurality of evaluation element regions, and
by differing the width of the resist pattern within the first semiconductor regions in each of the plurality of evaluation element regions, the minimum depth portion of the second semiconductor region in each of the plurality of evaluation element regions are different.
